(19) United States
(12) Patent Application Publication
(10) Pub. No.: US 2007/0232009 A1
(43) Pub. Date: Oct. 4, 2007

(54) SYSTEM AND METHOD FOR WAFER HANDLING IN SEMICONDUCTOR PROCESS TOOLS

(76) Inventor: Marko Schulz, Steina (DE)

Correspondence Address: J. Mike Amerson;Williams, Morgan & Amerson, P.C., Suite 1100, 10333 Richmond, Houston, TX, 77042, US

(21) Appl. No.: 11/551,530

(22) Filed: Oct. 20, 2006

(30) Foreign Application Priority Data
Mar. 31, 2006 (DE) 10 2006 015 089.9

(51) Int. Cl. H01L 21/331

(52) U.S. Cl. 438/366

(57) ABSTRACT

By providing an additional detector system for detecting the actual substrate position during transfer from and to a load lock station, the reliability of the corresponding process tool may be significantly enhanced. For example, an invalid position of the substrate during transfer from and to the load lock station may be reliably detected, in particular when a malfunction of the positioning system occurs. Consequently, a corresponding counter-measure may be taken, such as immediate interruption of the transfer operation, thereby reducing the risk of substrate damage or breakage.

### BACKGROUND OF THE INVENTION

1. Field of the Invention

Generally, the present invention relates to the field of fabricating integrated circuits, and, more particularly, to the operation of process tools, such as deposition tools, wherein substrate handling within the tools is performed on the basis of individual substrates.

2. Description of the Related Art

Today's global market forces manufacturers of mass produced products to offer high quality products at a low price. It is thus important to improve yield and process efficiency to minimize production costs. This holds especially true in the field of microstructure fabrication, for instance for manufacturing semiconductor devices, since, in this field, it is essential to combine cutting-edge technology with mass production techniques. It is, therefore, the goal of manufacturers of semiconductors, or generally of microstructures, to reduce the consumption of raw materials and consumables while at the same time improve yield and process tool utilization. The latter aspects are especially important since the equipment required in modern semiconductor facilities is extremely cost-intensive and represents the dominant part of the total production costs. At the same time, the process tools of a semiconductor facility have to be replaced more frequently compared to most other technical fields due to the rapid development of new products and processes, which may also demand correspondingly adapted process tools.

Integrated circuits are typically manufactured in automated or semi-automated facilities, thereby passing through a large number of process and metrology steps to complete the device. The number and the type of process steps and metrology steps a semiconductor device has to go through depends on the specifics of the semiconductor device to be fabricated. For instance, a sophisticated CPU requires several hundred process steps, each of which has to be carried out within specified process margins so as to fulfill the specifications for the device under consideration.

Consequently, the process tools operating on the basis of predefined process recipes substantially determine the throughput and yield of a semiconductor facility, wherein the individual reliability, availability and maintainability of the process tools has a significant influence on the overall yield and product quality. Since the critical dimensions of device features, such as the gate length of field effect transistors and the like, are continuously scaled down, the individual processes may have to be performed with increasingly tighter process margins. For example, many processes are performed on a single substrate basis in order to provide more uniform process conditions between the individual substrates. Moreover, contact of substrates to specific environmental conditions, such as moisture, unwanted gas components, such as oxygen, and the like, after and/or before certain processes may significantly affect the process result. Hence, sophisticated substrate handling techniques are typically used during the processing of substrates within a semiconductor plant, wherein, in many cases, a specified environment for each substrate is to be maintained. This is typically accomplished by using specific transport containers, which may be received at dedicated input and output stations of the device tools, also indicated as load ports, from which the individual substrates are forwarded to respective storage or process chambers.

The handling of the substrate is performed by appropriate load and unload mechanisms, wherein a control of the various phases of the loading and unloading operations may be controlled by an internal control system of the tool on the basis of sensor signals obtained from one or more appropriately positioned sensor elements, such as contact switches, encoders and the like. In many load and unload mechanisms, the accurate positioning of the substrates is critical for proper handling of the substrates, in order to avoid undue damage to the substrate which might otherwise result in a reduced yield of the respective substrate or even entail a total loss of the substrate under consideration. For example, in many manufacturing processes, the substrate environment is a critical factor, as pointed out above, and therefore respective process tools may comprise so-called load locks, which represent input or output areas for receiving or outputting substrates on the basis of a controlled environment in order to reduce an undue exposure to the clean room environment during the transfer of the substrate between the transport pod and one or more process chambers of the process tool. For instance, in many deposition processes, contamination of the substrate surface with certain species, such as oxygen, may result in a significant performance reduction of the subsequent process, such as an epitaxial growth process and the like. Thus, the substrate may be received in a load lock chamber providing a desired environment, wherein exposure to the ambient atmosphere during transfer into and from the load lock is minimized. However, during the substrate handling, when inserting or withdrawing the substrate into or from the load lock, the position of the substrate, for example the height position, has to be controlled with high precision, due to the constructional constraints of the load lock chamber, in order to avoid damage of the substrate. Consequently, in many process tools, such as single substrate chemical vapor deposition (CVD) tools, the positioning of the substrate during transfer to and from the load lock station is controlled on the basis of a closed loop control technique using an encoder connected to the conveyor mechanism of the load lock station.

Since modern process tools need to be operated in view of throughput over extended periods with a minimum amount of maintenance, a certain probability of loss of position information may exist, which may result in a misaligned substrate during the mechanical transfer, thereby possibly damaging the substrate or even causing breakage of the substrate. Thus, any encoder failure, wear out of the drive assembly components, such as drive belts, supply and control cables and the like, may entail severe process tool failures, which may lead to reduced yield and reduced tool reliability.

In view of the situation described above, there exists a need for a technique for increasing the reliability of the substrate handling in process tools, while avoiding one or more of the problems identified above or at least reducing the effects thereof.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present invention is directed to a technique for enhancing the reliability of process tools during substrate transfer. For this purpose, additional information is gathered from an independent sensor system that monitors the actual position of a substrate during the transfer from a load port of a process tool into the tool. In illustrative embodiments, the substrate may be transferred from a respective substrate carrier to one or more process tool chambers via a corresponding load lock station, wherein the positioning of the substrate during the transfer from and into the load lock station may be essential, at least in one spatial direction. Consequently, by providing position information on the actual position of the substrate, the overall reliability of closed loop positioning systems, typically relying on encoder information of the positioning hardware, may be significantly enhanced by using the additional “true” position information for “supervising” the closed loop positioning system. In this way, damage or breakage of substrates during transfer from and to process tools, for example, when comprising load lock stations for substantially maintaining the mini environment of the process tool, may be significantly reduced.

According to one illustrative embodiment of the present invention, a process tool comprises a load lock station configured to automatically receive and output a substrate. The process tool further comprises a positioning system comprising a first sensor element provided in the load lock station and a control unit operatively connected with the first sensor element, wherein the positioning system is configured to control a position of the substrate during transfer from and into the load lock station on the basis of a signal obtained from the first sensor element. Furthermore, the process tool comprises a position detector comprising at least one second sensor element configured to produce position information independently from the first sensor element to indicate a position of the substrate during transfer from and into the load lock station, wherein the position detector is configured to identify an invalid position of the substrate on the basis of the position information.

According to another illustrative embodiment of the present invention, a method comprises positioning a substrate during transfer to a load lock station of a process tool on the basis of a first sensor signal. Furthermore, it is determined whether the substrate is in an invalid position on the basis of a second sensor signal which is obtained independently from the first sensor signal. Finally, transfer of the substrate is interrupted when an invalid position is determined.

### BRIEF DESCRIPTION OF THE DRAWINGS

The invention may be understood by reference to the following description taken in conjunction with the accompanying drawings, in which like reference numerals identify like elements, and in which:

FIG. 1a schematically illustrates a process tool including a load lock station for receiving and outputting substrates, such as semiconductor substrates, wherein additional position information is obtained in order to supervise a closed loop positioning system according to illustrative embodiments of the present invention;

FIG. 1b schematically shows a portion of the process tool of FIG. 1a in a front view according to yet another illustrative embodiment including an optical distance measurement system for providing position information according to other illustrative embodiments of the present invention;

FIG. 1c schematically illustrates a front view of a sensor system including light barriers in accordance with still other illustrative embodiments; and

FIG. 1d schematically illustrates the process tool including a position detector for obtaining additional position information and a state monitor that may be used for estimating the status of the positioning system of a process tool in accordance with yet other illustrative embodiments of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present invention relates to techniques for enhancing process efficiency during substrate handling in process tools, wherein, in illustrative embodiments, the process tools may represent semiconductor process tools including a specific mini environment in order to reduce tool and substrate contamination. As previously explained, increasingly tighter constraints may be imposed on specific environmental conditions required for various process steps during the processing of sophisticated semiconductor devices. For example, in many processes, substrates may be treated individually, even though a plurality of process chambers may be integrated in a single process tool, wherein exposure to certain environmental conditions may have to be reduced in order to not unduly affect the process result, such as the deposition of a certain material compound, the epitaxial growth of semiconductor materials and the like. Consequently, load lock stations may be provided in a plurality of process tools which act as an interface between corresponding substrate carriers, such as FOUPs (front opening unified pod), or any other substrate carriers, which may establish a specified mini environment for a plurality of substrates during transport, and the actual process chamber(s) in which substrates may be individually processed. For example, a plurality of CVD process tools are currently available, such as the system Producer™ from Applied Materials Inc. and the like, in which the substrate is transferred from the substrate carrier into the load lock station and, after processing out of a load lock station on the basis of a transport mechanism, the positioning of which is to be precisely controlled in order to appropriately receive and discharge the substrate from the load lock station substantially without damage or even breakage of the substrate.

Consequently, highly sophisticated positioning systems are typically integrated in the respective transport mechanism in order to precisely control the position of respective conveyer arms and platforms on the basis of encoder information, which may be used for establishing a closed control loop. However, inappropriate positioning of the substrate during transfer may result in a complete loss of the substrate, thereby significantly reducing the reliability of the respective process tool as well as production yield. Consequently, the present invention provides an additional “supervising” detector system that may provide additional position information independently from any encoder information used for the closed loop control operation. Consequently, the additional position information may be efficiently used for monitoring the actual or “true” substrate position during the transfer of the substrate independently from the actual positioning system, wherein the additional position information may be of “higher priority” compared to position information on which is based the operation of the positioning system in order to allow an intervention, for instance by interrupting the transfer operation, when the additional position information does not comply with the status of the positioning system. Thus, incorrect positioning of the substrate due to, for instance, information loss within the closed loop positioning system, failure of any components and the like, may be reliably detected and appropriate countermeasures may be effected prior to actually damaging the substrate. In some illustrative embodiments, the additional position information may even be used for estimating the status of the positioning system and/or controlling the positioning system, for instance by re-adjusting respective target values of the positioning system, as will be described later on in more detail.

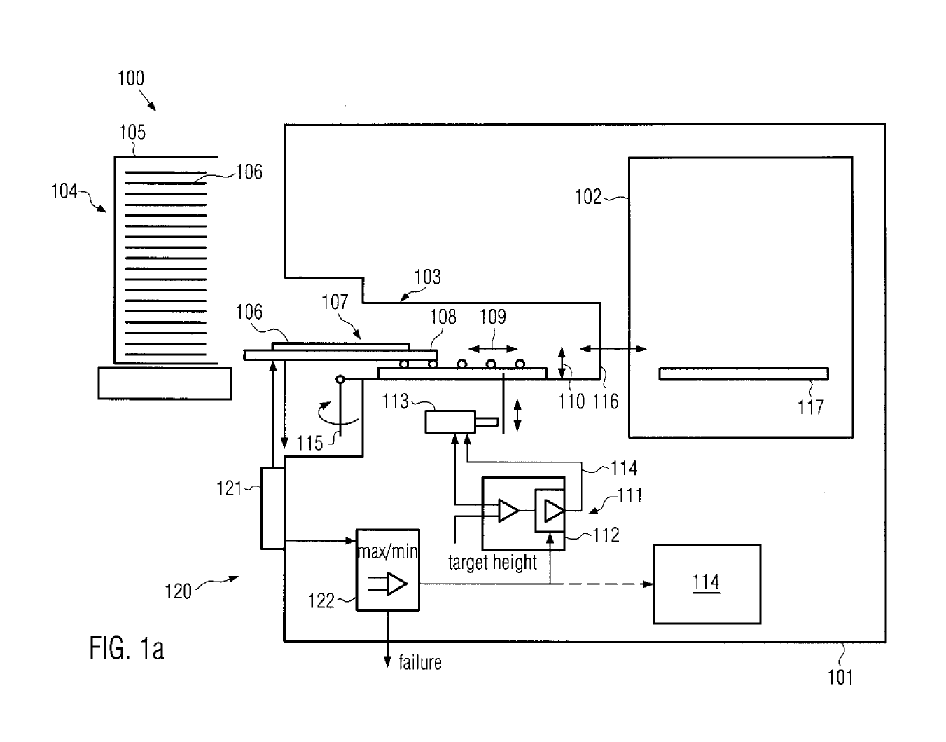

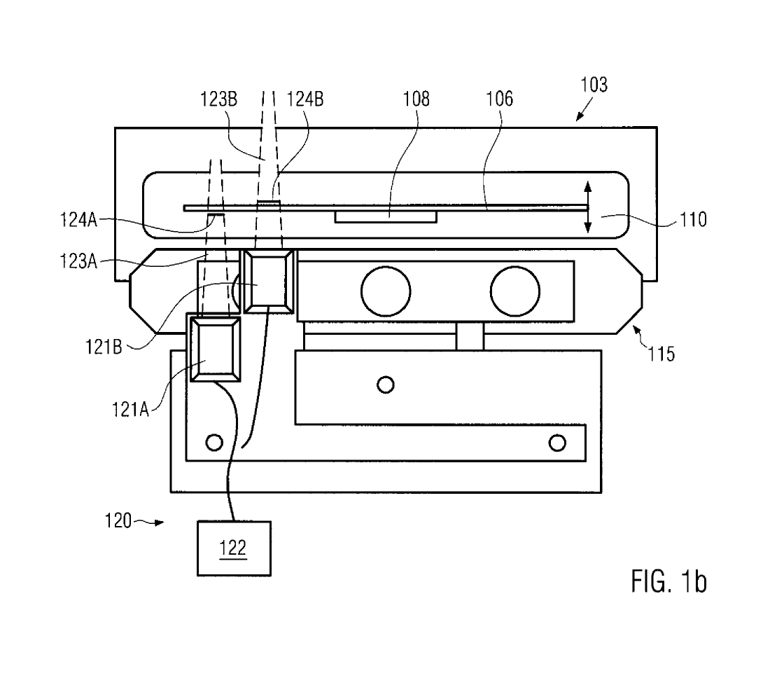

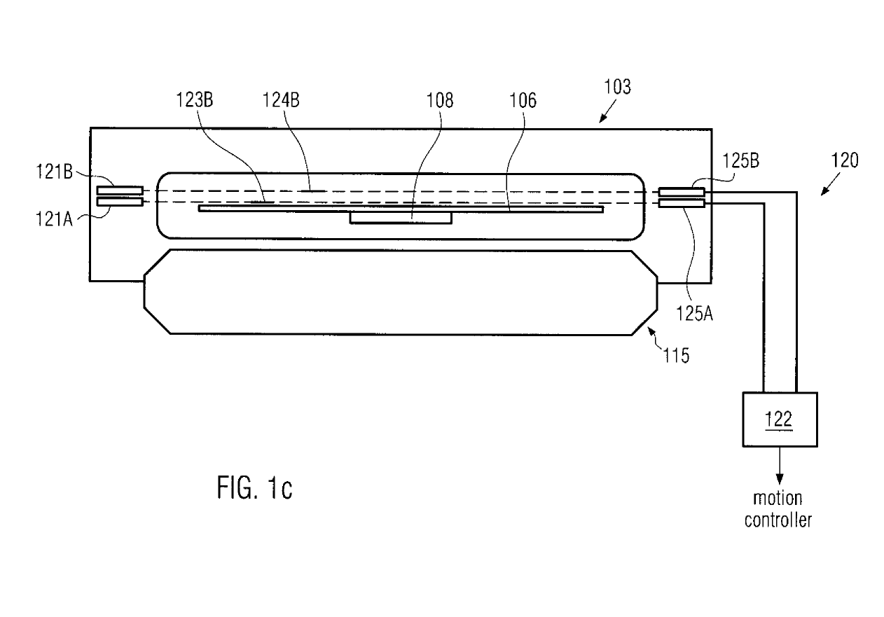

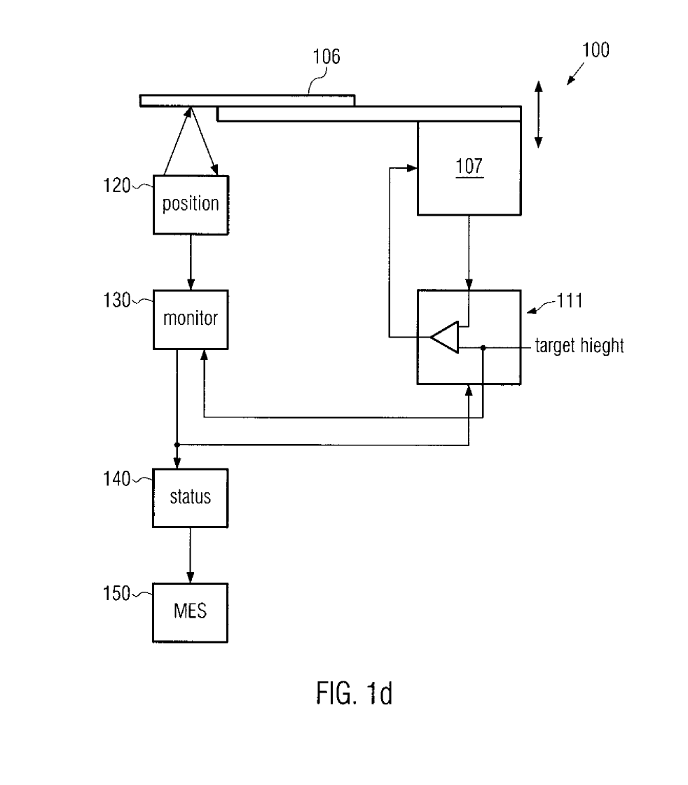

With reference to FIGS. 1a-1d, further illustrative embodiments of the present invention will now be described in more detail. FIG. 1a schematically illustrates a process tool 100 which may represent, in one illustrative embodiment, a process tool for processing semiconductor substrates, typically referred to as wafers. It should be appreciated that a process tool for processing semiconductor substrates is to be understood as any process tool, including metrology tools, for processing carrier materials, in and above which are formed microstructural devices, such as integrated circuits, optoelectronic devices, micromechanical devices, and any combination thereof. In one illustrative embodiment, the process tool 100 may represent a tool including one or more process chambers 102, in which a specific environment is to be established which may be significantly different from the ambient atmosphere within a clean room environment. For example, the one or more process chambers 102 may each be configured to receive a single substrate therein and to perform a specific process recipe on the basis of a well-defined environment, such as a deposition environment and the like. In one illustrative embodiment, the process tool 100 may represent a CVD deposition tool operating on a single substrate basis, such as the above-specified Producer™ from Applied Materials Inc. The one or more process chambers 102 may be provided within an appropriate tool housing 101 having a size and configuration compatible with constraints of modern semiconductor facilities. The tool 100 may further comprise one or more load ports 104 that are configured to receive one or more substrate carriers 105, which may include therein a specified number of substrates 106 to be processed or having been processed in the one or more process chambers 102. For example, the one or more load ports 104 may be configured to receive one or more substrate carriers 105 by an automatic transportation system and/or the one or more substrate carriers 105 may be delivered manually, depending on the degree of automation within the respective semiconductor facility.

The process tool 100 further comprises one or more load lock stations 103, which are configured to receive one substrate at a time from or to provide one substrate at a time to the carrier 105 by means of an appropriately configured robot or conveyer mechanism 107. The mechanism 107 may include a substrate support 108 that may receive one of the substrates 106 and transport the substrate 106 from and to the carrier 105 positioned on the load port 104, and to the one or more process chambers 102, possibly in combination with additional transport mechanisms (not shown). For this purpose, any appropriate drive assembly, including motors, actuators, belts, hydraulic components, electromagnetic components and the like, may be provided in order to perform the required motion in one or more horizontal directions 109 and a vertical direction 110, or any combination thereof, as is required for an appropriate positioning of the substrate 106. For convenience, any components of the robot mechanism 107 are illustrated in a simplified and illustrative manner only and it may be appreciated that respective conveyor mechanisms are well-established in the art. It may be appreciated, however, that the robot mechanism 107 may include a positioning system 111, which may be operatively connected to respective actuators and drive components, such as motors and the like, in order to cause an appropriate motion of the support 108 for transferring one of the substrate 106 from and into the carrier 105. The positioning system 11 1 may, in illustrative embodiments, comprise a control unit 112 receiving a sensor signal from a corresponding position sensor that is typically part of the robot mechanism 107. For instance, the sensor 113 may represent an encoder connected to a drive assembly component, such as an electric motor or any other actuator, in order to produce a corresponding electric signal in response to a motion of the support 108.

In illustrative examples, the control unit 112 may further be configured to operate on the basis of a target position, at least for one specified critical direction, so as to produce a corresponding differential output signal that is based on a difference between the sensor signal obtained from the encoder 113 and the respective target position. For example, as exemplarily illustrated in FIG. 1a, the sensor 113 may represent an electric motor comprising an encoder so that an output signal 114 may be supplied to the motor/encoder 113 for appropriately driving the support 108. In illustrative embodiments, the vertical or height position 110 within the load lock station 103 is a critical parameter with respect to transferring the substrate 106 from and to the carrier 105 and/or from and to the process chamber 102 due to, for instance, dimensional restrictions of the load lock station 103 in relation to the load port 104 and the carrier 105 in order to provide efficient substrate transfer from the carrier 105 into the load lock station 103 without substantial exposure to the ambient atmosphere. Thus, in this example, the positioning system 111 may at least operate on positional information obtained from the encoder 113 that relates to the vertical direction 110 in order to maintain the substrate 106 within a valid position range, at least in the direction 110, required for a proper transfer from and to the carrier 105.

The process tool 100 further comprises a position detector 120, which may comprise a further sensor element 121 configured to provide a further sensor signal independently from the signal obtained from the encoder 113 with respect to the position of the substrate 106 during transfer from and to the load station 103. In one illustrative embodiment, the sensor element 121 may be positioned external to the load lock station 103 to provide position information, at least with respect to one critical parameter, such as the vertical direction 110, in a substantially non-contact manner, thereby providing high reliability of the operation of the sensor 121 and a high degree of flexibility in appropriately positioning the sensor element 121 within the process tool 100. In one illustrative embodiment, the sensor element 121 may comprise a sensor component on the basis of optical radiation, such as a laser beam or any other appropriate radiation, such as microwave radiation, ultrasonic waves and the like. In one embodiment, the sensor element 121 may represent an optical distance measurement system which is positioned such that position information with respect to at least one spatial orientation, such as the vertical direction 110, may be obtained.

In one illustrative embodiment, the detector system 120 may further comprise a comparator unit 122, which is configured to receive position information from the sensor element 121 and to estimate whether or not the substrate 106 is in a valid position range during transfer from and to the load lock station 103. For example, the comparator unit 122 may include a maximum and a minimum acceptable value for one or more spatial orientations, such as the vertical direction 110, in order to estimate whether or not the actual position of the substrate 106 is between the minimum and maximum value. Moreover, the comparator unit 122 may be configured to indicate a corresponding deviation from a valid position range, for instance by causing an alarm, reporting to a supervising control system, such as an MES (manufacturing execution system), which is typically provided in sophisticated semiconductor facilities for coordinating the operation of the various process tools, such as the tool 100. In one illustrative embodiment, the comparator unit 122 may be further configured to interact with a tool controller 114, which may be configured to coordinate the operation of the entire process tool 100, or the comparator unit 122 may interact with the control unit 112 of the positioning system 110 in order to initiate an interruption of a transfer operation, depending on the respective position information provided by the sensor element 121.

During operation of the process tool 100, the carrier 105 may be delivered in an automatic or manual fashion. Thereafter, the carrier 105 may be opened and one of the substrates 106 may be transferred to the support 108 after opening a respective load lock door 115. Upon receiving the substrate 106, the support 108 has to be appropriately positioned, for instance with respect to the vertical direction 110, in order to transfer the substrate 106 without damage into the load lock station 103 and to properly position the substrate therein. After establishing a required environmental ambient within the load lock station 103, for instance by evacuating the station and/or by providing a specific gas mixture therein, the positioning system 111 may also control the movement of the substrate 106 from the load lock station 103 into the process chamber 102, wherein a corresponding load lock door 116 may be opened and the substrate 106 may be loaded onto a respective substrate stage 117 within the process chamber 102. During the corresponding substrate transfer, the critical position parameter, such as the position corresponding to the vertical direction 110, may also be controlled by the positioning system 111 on the basis of a respective target height in a closed loop control provided by the control unit 112. Thus, by continuously detecting an encoder signal from the encoder/motor 113, a respective error signal may be generated on the basis of a difference of the target value and the actual measurement value in order to eliminate the difference between these two values. For this purpose, any appropriate closed loop strategy, such as a PID (proportional integral differential) control and the like, may be used.

After the substrate 106 is processed in the chamber 102, transfer to the load lock station 103 may be initiated by the tool controller 114 and, after isolating the process chamber 102 by means of the load lock station 103, the substrate 106 may finally be transferred to the carrier 105. During one or more of the transfer operations, such as the transfer from the carrier 105 to the load lock station 103, as indicated in FIG. 1a, and/or during the transfer from the load lock station 103 to the process chamber 102 (not shown), the detector system 120 may provide additional position information on the basis of the signal provided by the sensor element 121. For the exemplary operational state as shown in FIG. 1a, the detector system 120 may provide information on the actual or true height position of the substrate 106 during transfer from the load lock station 103 to the carrier 105, which is used by the comparator unit 122 in order to estimate the position independently from any sensor signals used within the closed loop provided within the positioning system 111. For example, if the position information delivered by the sensor element 121 indicates an invalid position, for instance in the height direction 110, the comparator unit 122 may generate a corresponding message and, in illustrative embodiments, may “overrule” the control operation of the positioning system 111 by, for instance, interrupting the transfer process, thereby substantially avoiding or at least reducing the probability for severe damage of the substrate 106.

As previously explained, semiconductor process tools are typically operated in a substantially continuous manner over extended time periods in order to increase tool utilization, thereby reducing overall production costs. Consequently, the complex conveyer mechanism 107 may suffer from wear out of specific components, such as drive belts, cables and the like. Consequently, the closed loop control operation of the system 111 may in some instances result in inappropriate positioning of the substrate 106, for instance when a signal delivered from the encoder/motor 113 may no longer appropriately reflect the actual position of the support 108, or when a loss of position information may occur during hardware or software failures in the system 111. In this case, the detector system 120 provides, in a highly reliable manner, i.e., without relying on mechanical sensor components, an additional position information which may also indicate the actual “output” of the positioning system 111, thereby providing the potential for monitoring the quality of the positioning process provided by the system 111. Thus, in case of a severe deviation, based on the position information obtained by the detector system 120, countermeasures may be taken, such as interrupting the transfer operation and/or monitoring the status of the positioning system 111 and/or controlling the positioning process on the basis of the additional position information obtained by the detector system 120, as will be described in more detail later on. Consequently, since failures in positioning the substrate 106 during transfer may be detected more reliably on the basis of the detector system 120, the overall reliability as well as the overall production yield may be significantly enhanced.

FIG. 1b schematically illustrates a front view of a part of the process tool 100 in accordance with other illustrative embodiments, in which an optical distance measurement system on the basis of triangulation and, in one embodiment, on the basis of an area sensitive sensor device is provided within the detector system 120 of FIG. 1a. In the process tool 100 of the embodiment as shown in FIG. 1b, the detector system 120 may comprise a first sensor component 121A and a second sensor component 121B which are disposed such that both sensor components 121A, 121B may face the back side of the substrate 106 during transfer of the substrate 106, i.e., before entering the load lock station 103 or after leaving the same. Consequently, the sensor components 121A, 121B may optically gather position information of the substrate 106 on the basis of the substrate back side, which provides substantially constant reflectivity, irrespective of the type of products to be formed in and on the substrate 106 and the type of process to be performed in other process tools 100. Consequently, reliable position information may be obtained substantially independently from the specifics of the substrate 106. In one illustrative embodiment, the sensor components 121A, 121B may be provided in the form of a laser-based triangulation system, wherein the sensor components 121A, 121B may be appropriately positioned such that the combined measurement range enables the detection of an invalid substrate position. For example, the sensor component 121A may have a measurement range 123A that allows gathering position information with respect to the critical parameter 110 in order to reliably detect a deviation, wherein, in one illustrative embodiment, the measurement range 123A may be selected such that a first limit 124A of the measurement range 123A may simultaneously represent a lower limit in the critical height direction 110.

In one specific embodiment, area detecting sensors, available from Keyence, Inc. under the trademark LV H47, may be used, which provide a fixed detector range from approximately 55-85 mm. For this type of sensor, the detection of an object is restricted to this detection range. If objects, such as the substrate 106, the support 108, the load lock door 115 and the like, are outside of this detection range but within the range of the respective laser radiation, the presence of such objects is ignored.

Consequently, a high degree of reliability and sensitivity may be obtained by a corresponding arrangement, since the sensor component 121A may be used, in some embodiments, as a “digital” sensor element providing a sensor signal whenever the limit 124A is reached or exceeded in the downward direction 110. Similarly, a measurement range 123B of the sensor component 121B may be positioned such that a lower limit 124B of the range 123B may simultaneously define an upper limit of an allowable height position of the substrate 106. Thus, also in this case, the sensor component 121B may be used as a digital sensor device, which may reliably indicate whenever the critical limit 124B is exceeded in the upward direction. Consequently, by a corresponding arrangement with respective offsets, as shown in FIG. 1b, a deviation on both vertical directions may be highly reliably detected, on the basis of input entities, such as light intensity and the like. Based on the above described area-sensitive sensor elements, the height offset and also an oblique position of the support 108 and thus of the substrate 106 may be detected. Any support means (not shown) for the sensor components 121A and 121B may be attached in such a manner that existing process tools may also be provided with the components 121A, 121B without significant modification. Moreover, the support means may also comprise an appropriate adjustment system, such as scales and the like, in order to enable an appropriate positioning and re-positioning of the components 121A, 121B.

Moreover, by correspondingly arranging the respective measurement ranges 123A and 123B, more detailed information may be obtained with respect to the degree of deviation from a valid position range defined by the limits 124A and 124B. Consequently, a valid position of the substrate 106 may be rapidly detected on the basis of the respective output signals of the components 121A, 121B whenever the substrate 106 is outside of the respective measuring ranges 123A, 123B. Upon detecting a substrate 106 in one of the measuring ranges 123A, 123B, the comparator unit 122 may determine an invalid position status and may notify the tool controller 114 and/or the control unit 112 and/or any other supervising control system for initiating an appropriate control activity, such as the interruption of the transfer process.

In other illustrative embodiments, one or both of the sensor components 121A, 121B may be configured to estimate an absolute position of the substrate 106, i.e., of the back side thereof, for instance on the basis of triangulation, so that the respective position information may be used to determine the actual position, which may then be compared with a valid range of position coordinates in order to estimate whether or not the substrate 106 is in a valid position with respect to the critical direction 1 10. For example, in the embodiment shown in FIG. 1b, one or both of the components 121A, 121B may be positioned such that the substrate 106 is within one or both of the measurement ranges 124A, 124B for any allowed height position or for a wide span of possible height positions, including invalid height positions. In this way, the position information provided by one or both of the sensor components 121A, 121B may then be compared within the unit 122 with a respective target range, wherein, in some illustrative embodiments, a deviation from a respective target value may also be calculated and may be used for estimating the status of the positioning system 111, as will be described in more detail later on.

Thus, the position information may be obtained by a single sensor component 121A, 121B or, in other embodiments, as shown, from both components 121A, 121B, wherein a certain degree of redundancy and thus additional reliability may be provided, in that one of the signals may be used to “verify” the other sensor signal. For example, triangulation systems or area-sensitive sensor systems as described above on the basis of laser irradiation may be available, which provide a measurement range of several centimeters with a positional resolution of several micrometers. Consequently, the validity of the position of the substrate 106 may be determined with high precision and reliability so that the detector system 120 may represent a supervising monitor system, the position information of which may be considered as having a higher priority compared to the positioning system 111, wherein the configuration of the detector system 120 may provide increased reliability compared to the positioning system 111, due to the lack of complex mechanical components as well as a certain degree of redundancy. Moreover, the information obtained from the detector system 120 may be obtained directly from the substrate 106 during the transfer operation, thereby enabling the evaluation of the “true” position and thus the result of the positioning system 111, which may exhibit a certain drift over time even if actual failures in one or more of the components of the system 111 may not occur. For example, due to a gradual wear out of one of the components in the robot mechanism 107 (FIG. 1a), the mechanical response of the mechanism 107 to the corresponding drive signal from the control unit 112 may result in a deviation from a target position, even though the signal obtained from the encoder/motor 113 may substantially coincide with the respective target value. Consequently, the position information obtained by one or more of the sensor components 121A, 121B may be used for monitoring and/or controlling the positioning system 111.

In one embodiment, when the components 121A, 121B represent area-sensitive sensors, the presence of the substrate 106 and/or of the support 108 within one of the measurement ranges 123A, 123B may be detected in case of a failure during substrate transfer, thereby indicating that the substrate 106 is no longer within the valid range defined by the upper and lower limits 124B, 124A. Then, the robot mechanism 107 may be controlled such that the support 108 may return the substrate 106 into the load lock station 103, discontinue its activity and signal the height deviation for the current transfer event by any appropriate error indication.

FIG. 1c schematically illustrates a portion of the process tool 100 in a front view according to still other illustrative embodiments of the present invention. In the embodiments shown, the substrate transfer operations of the load lock system 103 may be monitored by the detector system 120, which may comprise one or more light barriers so as to define at least the lower limit 124A and the upper limit 124B for determining in between a range of allowable positions of the substrate 106 during transfer from and to the load lock station 103. The detector system 120 may comprise a first detector component, which may include a radiation emitting element 121A and a radiation receiving element 125A, such as a light emitting device and a light receiving device, respectively. Similarly, a second detector component for defining the upper limit 124B may comprise a radiation emitting device 121B and a radiation receiving device 125B. The corresponding receiving elements 125A, 125B may be connected to the comparator unit 122 in order to estimate the position of the substrate 106 during transfer. For example, during positioning and transferring the substrate 106, the corresponding operation may result in an invalid height position of the substrate 106, for instance due to a failure in the positioning system 111. Consequently, both light barriers defined by the upper and lower limits 124A, 124B may not be interrupted, indicating that the substrate 106 is below the lower limit 124A. Similarly, if the substrate 106 is positioned so as to be located within the valid range defined by the lower and upper limits 124A, 124B, the light barrier provided by the elements 121A and 125A is interrupted, while the second light barrier defined by the elements 121B and 125B may be not interrupted. Likewise, if the substrate 106 is positioned beyond the upper limit 124B in the upward direction, both light barriers may be interrupted. Hence, based on the “digital” information provided by the light barriers, the comparator unit 122 may reliably determine whether or not the substrate is appropriately positioned during transfer.

In still other illustrative embodiments, a greater number of light barriers may be used in order to provide a higher spatial resolution with respect to the height position of the substrate 106. For instance, one or more additional light barriers within the valid range or outside of the valid range may provide additional information with respect to the positioning accuracy of the positioning system 111.

It should be appreciated that the detector system 120 as described with reference to FIGS. 1a-1c may be readily adapted to the characteristics of the respective conveyor mechanism 107 by selecting an appropriate sensor regime. For example, if a conveyor mechanism 107 is used in which the back side of the substrate 106 is not appropriately exposed during the substrate transfer, and an indirect position information, for instance obtained by the corresponding back side of a substrate support and the like, is considered inappropriate, additionally or alternatively the sensor regime as shown in FIG. 1c may be used in order to reliably detect the position of the surface of the substrate 106 during the transfer, irrespective of the actual configuration of the support 108. Moreover, since, in the system as illustrated in FIG. 1c, the sensor signal is based on a substantially digital behavior, i.e., interruption or non-interruption, the corresponding sensor signal is substantially insensitive with respect to the reflectivity of the corresponding substrate surface, thereby enabling a reliable position detection prior to and after any processing within the process chamber 102, irrespective of any modification of the optical characteristics of the resulting surface.

FIG. 1d schematically shows the process tool 100 according to further illustrative embodiments in which the position information obtained by the detector system 120 is used, in addition or alternatively to indicating a failure during the substrate transfer, for other control purposes. Thus, in one illustrative embodiment, the process tool 100 may comprise a state monitor 130 operatively connected to the detector system 120 in order to obtain position information of the substrate 106 therefrom. Moreover, the state monitor 130 may be configured to evaluate the “process output” of the positioning system 111 when operating the conveyor mechanism 107. That is, the state monitor 130 may be configured to estimate the positioning accuracy of the system 111 on the basis of the position information obtained from the detector system 120. For example, the state monitor 130 may receive or may have stored therein a respective target value for a critical position, such as a respective height position of the substrate 106 prior to receiving or after outputting the substrate 106 from the load lock station 103. By determining a deviation from the target value on the basis of the actual position information of the detector system 120, a corresponding evaluation of the performance of the positioning system 111 may be established. For instance, systematic drifts may be identified even though the substrate 106 may be processed by the positioning system 111 so as to be within a valid position range and corresponding countermeasures may be initiated on the basis of a corresponding indication of a systematic drift by the state monitor 130. In some illustrative embodiments, the state monitor 130 may further be configured to interact with the positioning system 111, for instance by adapting the respective target value or any other appropriate control parameter used by the positioning system 111 for operating the conveyor mechanism 107. In this way, the positioning system 111 may be re-adjusted on the basis of the position information obtained by the detector system 120, wherein, as previously explained, the respective sensor signals may be obtained independently from any sensor systems internally provided in the conveyor mechanism 107 and/or the positioning system 111.

In some illustrative embodiments, the state monitor 130 may act as a “supervising” control system in which the position information received from the detector system 120 may be appropriately processed, for instance by determining statistically relevant values, such as an EWMA (exponentially weighted moving average) and the like, in order to maintain the positioning accuracy of the system 111 in combination with the conveyor mechanism 107 within a desired target range, wherein additionally an immediate response may be triggered as soon as a severe mis-positioning of the substrate 106 is detected, as is also described above with reference to FIGS. 1a-1c.

Consequently, enhanced reliability may be obtained by significantly reducing the risk for damage or breakage of substrates during transfer due to the immediate response of the detector system 120 upon detection of an inappropriate substrate position, while also the long-term reliability of the positioning system 111 may be significantly enhanced on the basis of the additional position information substantially reflecting the actual process output of the positioning system 111.

In still other illustrative embodiments, a status estimator 140 may be provided, which may be connected to the state monitor 130 and which may be connected, in some illustrative embodiments, to a supervising control system such as an MES (manufacturing execution system) 150, as is typically provided in sophisticated semiconductor facilities for coordinating the operation of a process tool 100 in a complex manufacturing environment. The status estimator 140 may be configured to evaluate the actual “hardware” status of the positioning system 11 1 and/or the conveyor mechanism 107 on the basis of process information obtained from the state monitor 130. As previously described, upon detection of an invalid position of the substrate 106, a corresponding indication or alarm may be triggered by the detector system 120, which may represent a situation in which the status of the positioning system 111 and/or the conveyor mechanism 107 may be readily determined. However, as previously described with reference to the state monitor 130, more subtle deviations from a desired operational behavior may be detected on the basis of the detector system 120, which may then be evaluated by the status estimator 140 with respect to certain criteria, such as wear out of hardware components, expected mean time to maintenance and the like. For instance, for a corresponding drift of the positioning system 111, which may be compensated for by the state monitor 130 in the above-described manner, the status estimator 140 may estimate the current status of the positioning system 111 and/or the conveyor mechanism 107 by referring to appropriately defined reference data. For example, a systematic drift during the operation of the positioning system 111 may be identified, on the basis of respective experimental data, as a gradual deterioration of one or more components, and hence the status estimator 140 may provide a corresponding evaluation wherein, in some embodiments, an estimated prediction with respect to the future operational behavior of the positioning system 111 and/or the conveyor mechanism 107 may also be provided. For this purpose, a difference between the reference data and the corresponding position data or correction data or any other meaningful values derived on the basis of the position data may be calculated and used as a measure of the current hardware status and may also be used in order to predict the future behavior of the system 111 and/or the conveyor mechanism 107. The status estimator 140 may provide a corresponding status estimation value and/or a quantitative prediction of the future operational behavior to the MES 150 in the form of an appropriate process message. Consequently, based on the status information provided by the estimator 140, the MES 150 may appropriately schedule or re-schedule the process flow involving the tool 100 to obtain high tool utilization with increased reliability.

As a result, the present invention provides a technique for enhancing the substrate handling process in sophisticated semiconductor process tools in that additional positional information is gathered and used to detect an invalid substrate position during a transfer operation. For this purpose, in some illustrative embodiments, a non-contact position sensor system may be used, in which the actual substrate position may be determined independently from the sensor elements, such as motors, encoders and the like, used in the respective positioning system. Consequently, a high degree of robustness and thus reliability is provided for the independently obtained position information so that, based on this information, the operation of the positioning system, including a closed loop process control, may be overruled, for instance by interrupting a transfer operation, or by interacting with the closed control loop in order to enhance the control stability thereof. For example, in some illustrative embodiments, the control function of the closed control loop may be adjusted on the basis of the additional position information obtained from the detector system in the form of feedback data to increase the precision of the control operation for one or more subsequently processed substrates. For example, detector systems on the basis of laser triangulation systems may be used in order to determine the position of the substrate during a transfer operation, wherein the sensor information may be obtained in the form of a substantially digital information or as a substantially analog information, thereby providing the potential for accurately monitoring the operational behavior of the respective positioning system. In this case, the sensor elements may be positioned such that a high degree of process uniformity may be obtained, in that the back side of the substrate may be used to reflect an optical beam, thereby obtaining moderately stable process conditions. In still other illustrative embodiments, other optical detection means, such as light barriers, may be provided to independently obtain positional information with high reliability, thereby also providing a high degree of flexibility in adapting the configuration of the detector system to a variety of process tool configurations.

In one illustrative embodiment, the detector system as described above may be provided in deposition tools, such as CVD tools, epitaxial growth tools and the like, in which typically load lock stations may be used for enhanced performance. Consequently, the present invention may also be efficiently used in combination with existing tool configurations, thereby contributing to significantly enhanced tool reliability without adding significant additional costs. Moreover, in other applications, the hardware status of the positioning system and/or the conveyor mechanism may be effectively estimated in order to gain valuable information with respect to tool performance and utilization.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A process tool, comprising:
a load lock station configured to automatically receive and output a substrate;
a positioning system comprising a first sensor element associated with said load lock station and a control unit operatively connected with said first sensor element, said positioning system being configured to control a position of said substrate during transfer from and into said load lock station on the basis of a signal obtained from said first sensor element; and
a position detector comprising at least one second sensor element configured to produce position information independently from said first sensor element to indicate a position of said substrate during transfer from and into said load lock station, said position detector being configured to identify an invalid position of said substrate on the basis of said position information.

2. The process tool of claim 1, wherein said position detector is operatively connected to a tool controller of said process tool and is further configured to discontinue processing of said substrate when said detected position of said substrate is an invalid position.

3. The process tool of claim 1, wherein said at least one second sensor element is a non-contact sensor element.

4. The process tool of claim 3, wherein said position detector comprises an optical distance measurement system.

5. The process tool of claim 4, wherein said at least one second sensor element of said optical distance measurement system is positioned to irradiate a back side of said substrate.

6. The process tool of claim 5, wherein said optical distance measurement system comprises at least two second sensor elements, said at least two second sensor elements commonly defining a valid range of positions for said substrate.

7. The process tool of claim 4, wherein said optical distance measurement system comprises one or more light barriers positioned to detect a specific height position of said substrate.

8. The process tool of claim 1, further comprising a state monitor operatively connected to said position detector and configured to estimate an operational state of said positioning system on the basis of said position information.

9. The process tool of claim 8, wherein said state monitor is further configured to receive a target value used by said positioning system and to estimate an operational state of said positioning system on the basis of said target value and said position information.

10. The process tool of claim 9, wherein said state monitor is further configured to evaluate the status of one or more components of said positioning system on the basis of said operational state.

11. The process tool of claim 1, wherein said position detector is operatively connected to said positioning system and said positioning system is configured to control the position of a subsequent substrate on the basis of said position information provided by said at least one second sensor element for said substrate.

12. The process tool of claim 1, wherein said position detector is configured to determine a height position of said substrate during transfer from and into said load lock station.

13. A method, comprising:
positioning a substrate during transfer to a load lock station of a process tool on the basis of a first sensor signal;
determining whether said substrate is in an invalid position on the basis of a second sensor signal, said second sensor signal being obtained independently from said first sensor signal; and
interrupting transfer of said substrate when an invalid position is determined.

14. The method of claim 13, wherein determining whether said substrate is in an invalid position comprises optically detecting a position of said substrate.

15. The method of claim 14, wherein optically detecting a position of said substrate comprises directing an optical beam to a back side of said substrate and detecting said position using a reflected beam reflected from said back side.

16. The method of claim 13, further comprising monitoring said positioning process on the basis of said second sensor signal.

17. The method of claim 16, wherein monitoring said positioning process further comprises evaluating a result of said positioning process on the basis of said second sensor signal and a target value used for positioning said substrate.

18. The method of claim 13, further comprising controlling said positioning process on the basis of said second sensor signal.

19. The method of claim 18, wherein a priority of said second sensor signal is higher than a priority of said first sensor signal when controlling said positioning process.

20. The method of claim 13, further comprising controlling the positioning of one or more subsequent substrates on the basis of said second sensor signal obtained from said substrate.

21. The process tool of claim 12, wherein said position detector comprises a first area-sensitive sensor system and a second area-sensitive sensor system arranged to define an upper limit and a lower limit for a valid height position of said substrate during transfer.

22. The process tool of claim 21, wherein said first and second area-sensitive sensor systems are arranged at different heights to define said upper and lower limits.
